(19) United States
(12) Patent Application Publication
(10) Pub. No.: US 2005/0153517 A1
(43) Pub. Date: Jul. 14, 2005

(54) Modifying U-shaped window spacers to receive internal blinds or other hardware

(76) Inventors: John C. Kim, Bloomfield Hills, MI (US); Sun-Hee Lee, Bloomfield Hills, MI (US)

Correspondence Address: John G. Posa;Gifford, Krass, Groh, Sprinkle,, Anderson & Citkowski, P.C., 280 N. Old Woodward Ave., Suite 400, Birmingham, MI, 48009-5394, US

(21) Appl. No.: 10/972,702

(22) Filed: Oct. 25, 2004

Related U.S. Application Data
(60) Provisional application No. 60/514,409, filed on Oct. 24, 2003.

(51) Int. Cl. H01L 21/20

(52) U.S. Cl. 438/396

(57) ABSTRACT

Devices and methods are employed to convert an open, U-shaped flex-type window spacer to provide a surface for mounting an interior blind or other hardware. Such existing spacers have a generally U-shaped cross section and a groove with a width facing into a sealed cavity between panes of glass and opposing parallel lips on either side of the groove. The preferred embodiments include an elongate panel having an inner surface, an outer surface, and a width greater than the width of the groove, and barbs extending from the inner surface and configured to be retained by the lips so as to hold the panel in position with the outer surface facing into the sealed cavity. According to a basic configuration, the outer surface of the panel is generally flat, though the panel has an L-shaped cross section or may provide a clip to hold a blind control mechanism in position.

### REFERENCE TO RELATED APPLICATION

This application claims priority from U.S. Provisional Patent Application Ser. No. 60/514,409, filed Oct. 24, 2003, the entire content of which is incorporated herein by reference.

### FIELD OF THE INVENTION

This invention relates generally to sealed windows and, in particular, to devices and methods for modifying flex-type window spacers to receive internal blinds or other hardware.

### BACKGROUND OF THE INVENTION

Louvered or “venetian” blinds that are disposed internally to sealed windows are popular because blinds do not need to be cleaned. Commonly, the blind components are mounted and placed relative to “spacers” used to maintain opposing sheets of glass at a desired distance.

FIG. 1 is a drawing that shows a typical spacer, which may be formed from a metal such as aluminum, plastic or other materials. An advantage of this spacer is that it provides an edge 102 upon which an internal blind may be mounted or otherwise retained.

Another type of spacer is the so-called “Intercept” spacer, which is available from PPG Industries, and shown in FIG. 2. According to the manufacturer, this design is advantageous because the use of an open, U-shaped channel allows for a certain degree of flexing which improves the integrity of the seal to the glass. However, this design foregoes the flat surface against which blinds are typically mounted or guided.

### SUMMARY OF THE INVENTION

This invention resides in devices and methods for converting an open, U-shaped flex-type window spacer so as to provide surfaces appropriate to mounting an interior blind or other hardware. Such existing spacers have a generally U-shaped cross section and a groove with a width facing into a sealed cavity between panes of glass and opposing parallel lips on either side of the groove.

The preferred embodiments include an elongate panel having an inner surface, an outer surface, and a width greater than the width of the groove, and barbs extending from the inner surface and configured to be retained by the lips so as to hold the panel in position with the outer surface facing into the sealed cavity.

According to a basic configuration, the outer surface of the panel is generally flat, though the panel has an L-shaped cross section or may provide a clip to hold a blind control mechanism in position.

### BRIEF DESCRIPTION OF THE DRAWINGS

FIG. 1 is a shows a prior-art spacer configuration;

FIG. 2 is a shows another type of prior-art spacer;

FIG. 3 is a cross-sectional drawing of a preferred embodiment of the invention utilizing a plate with barbs that fit into a box-type spacer;

FIG. 4 is a cross-sectional drawing of an alternative embodiment of the invention;

FIG. 5 is a drawing which shows different types of clips constructed in accordance with the invention for the top, sides and bottom of an OEM blind configuration;

FIG. 6 is a drawing similar to that shown in FIG. 5 for a different type of an OEM blind configuration; and

FIG. 7 is a close-up cross-sectional view of a top header clip according to the invention in place with an OEM blind.

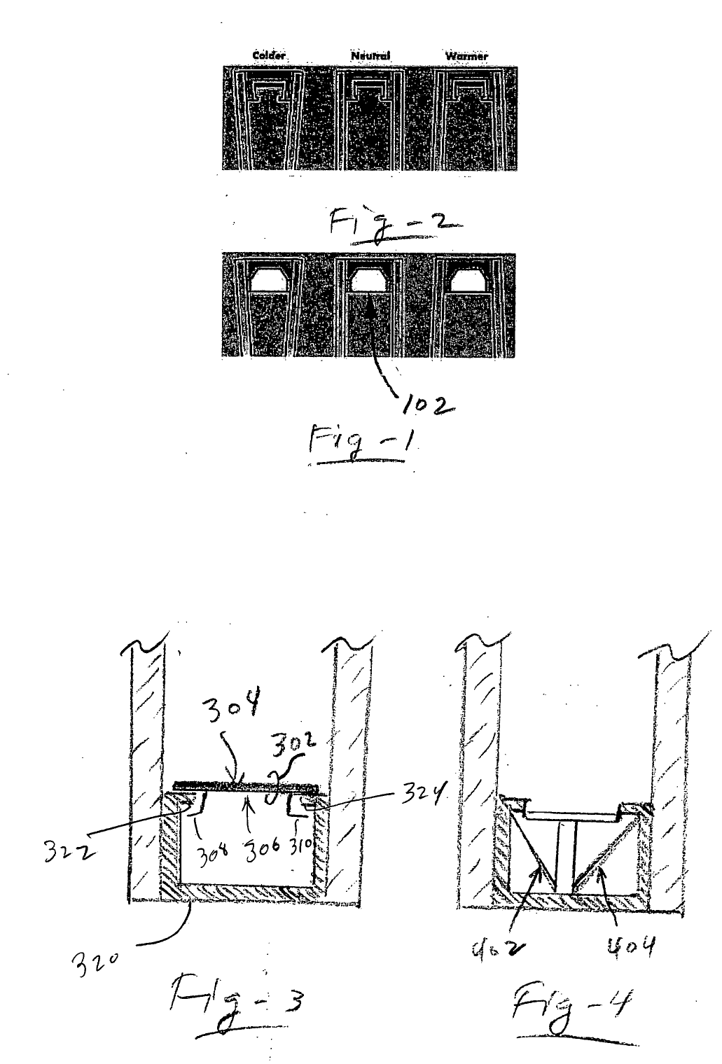

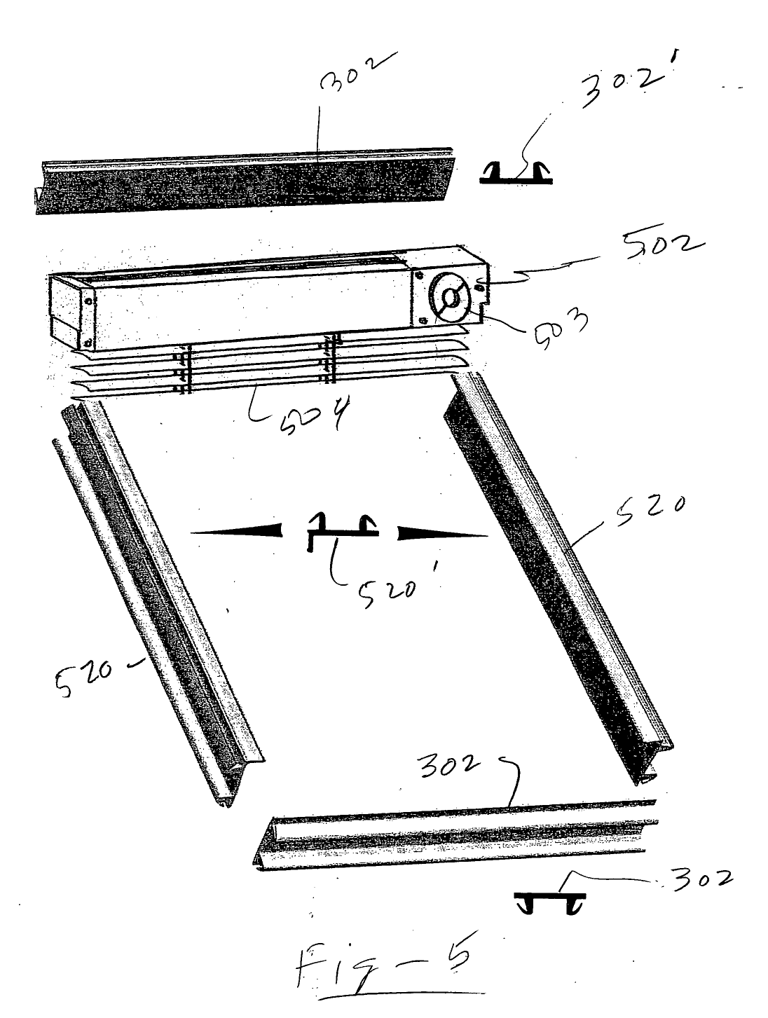

### DETAILED DESCRIPTION OF THE INVENTION

This invention improves upon the existing art through apparatus and methods of modifying an open, U-shaped or “Intercept” type window spacer so as to provide a surface against which interior blinds or other in-window devices may be installed.

In one embodiment, shown in FIG. 3, the invention takes the form of a clip 302 having an outward surface 304 and an inward surface 306 with side barbs 308, 310. The spacer, shown at 320, has front lips 322, 324, allowing the clip 302 to slide or flex into position with barb 308 being trapped behind lip 322 and barb 310 trapped behind lip 324. This provides a surface (304) similar to those found in box-type spacers. Note that even with such modification, the advantages of the flex-type spacer is maintained.

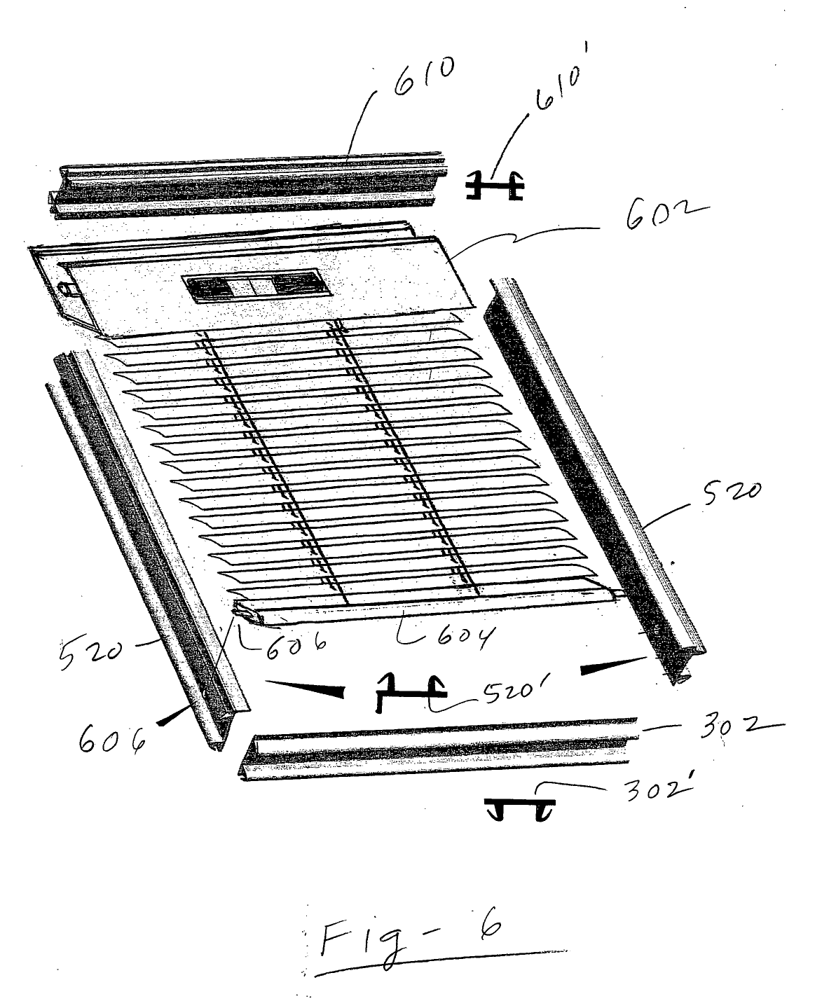

FIG. 4 shows an alternative embodiment utilizing spring-biased barbs 402, 404 that flex toward one another, allowing the component to be installed in the U-shaped spacer such that, once received, the component device in place.

To accommodate different edges of typical sealed windows, different types of inserts are provided. FIG. 5, for example, shows the way in which a first type of sealed OEM mechanism 502 with blinds 504 would be accommodated. In this case, rotation of through-the-glass magnetic coupling 503 not only causes the blinds 504 to tilt, but also to move up and down to more extended rotation. To accommodate this mechanism, a top insert 506, having a cross section 506′ would be used, and the mechanism 502 would be butted up against the exposed outer surface of the insert 506 once installed. For a pleasing aesthetic appearance, side rails 520, each with a cross section 520′ would be used on either side of the assembly, and a bottom clip 530, having a cross section 530′, identical to 506 and 302 in FIG. 3, would be used at the bottom.

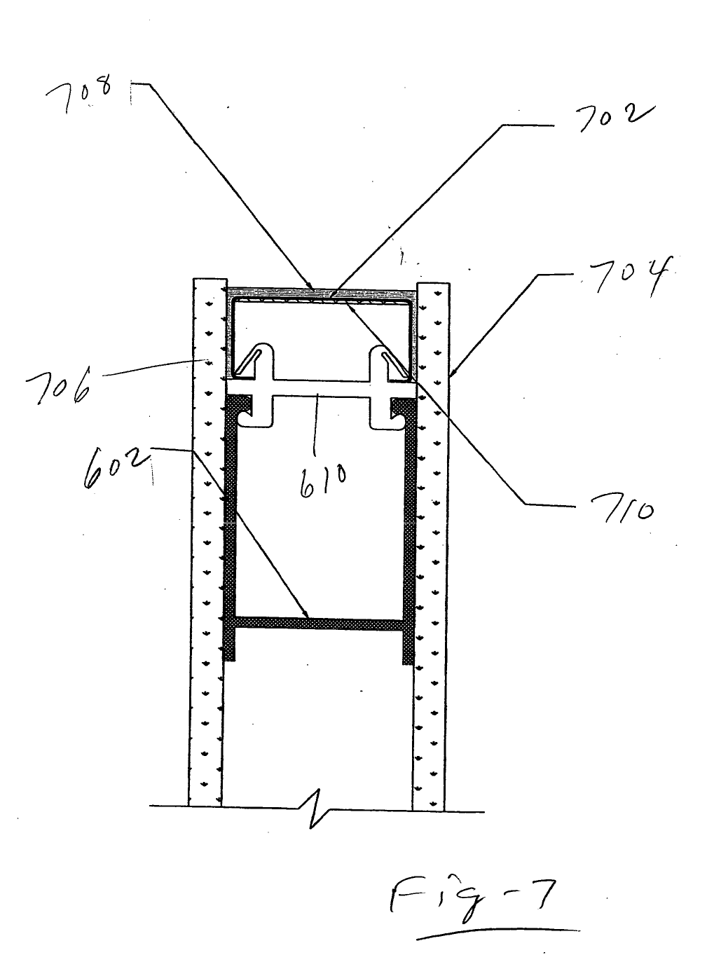

FIG. 6 is a drawing which shows a construction made possible by the invention for use with a blind mechanism 602 having a top U channel, and a control mechanism that provides only a tilt function. In this case, the bottom louver 604 has side protrusions 606 which fit into holes 608 formed in the side rails 520. While an insert 302 may also be used at the bottom of this configuration, given the U-shaped top portion of the mechanism 602, a spacer 610 having a cross section 610′ is preferably used instead. The interaction of the various top components are depicted in FIG. 7. The intercept spacer is shown at 602, between panes of glass 604, 606. The sealant is shown at 608, and the preferred use of a desiccant is shown at 710. The cross section of the control mechanism is depicted at 602, with the use of the inventive spacer shown at 610.

1. An insert for a window spacer having a generally U-shaped cross section and a groove with a width facing into a sealed cavity between panes of glass and opposing parallel lips on either side of the groove, the insert comprising:
an elongate panel having an inner surface, an outer surface, and a width greater than the width of the groove; and
barbs extending from the inner surface and configured to be retained by the lips so as to hold the panel in position with the outer surface facing into the sealed cavity.

2. The insert of claim 1, wherein the outer surface is generally flat.

3. The insert of claim 1, wherein the panel has an L-shaped cross section.

4. The insert of claim 1, wherein the outer surface includes a clip to hold a blind control mechanism.

5. A method of converting an open, U-shaped flex-type window spacer to provide a surface for mounting an interior blind or other hardware, comprising the steps of:
providing a member having a surface against which such hardware may be mounted; and
installing the member relative to the U-shaped channel of the window spacer.

6. A method of converting an open, U-shaped flex-type window spacer to provide a surface for mounting an interior blind or other hardware, comprising the steps of:
providing a member having a surface against which such hardware may be mounted; and
installing the member relative to the U-shaped channel of the window spacer.
